(19) United States
(12) Patent Application Publication
(10) Pub. No.: US 2025/0047090 A1
(43) Pub. Date: Feb. 6, 2025

(54) Fuse Circuit Assembly for An Energy System and Energy System

(71) Applicant: Vitesco Technologies GmbH, Regensburg (DE)

(72) Inventors: Rainer Gietl, Regenstauf (DE); Stefan Eichenseher, Wenzenbach (DE); Martin Meier, Walderbach (DE); Stefan Rockinger, Stefan (DE)

(73) Assignee: Vitesco Technologies GmbH, Regensburg (DE)

(21) Appl. No.: 18/921,415

(22) Filed: Oct. 21, 2024

Related U.S. Application Data
(63) Continuation of application No. PCT/EP2023/059712, filed on Apr. 13, 2023.

(30) Foreign Application Priority Data
Apr. 29, 2022 (DE) 10 2022 204 201.8

(51) Int. Cl. H02H 3/08; H03K 17/687

(52) U.S. Cl. CPC H02H 3/08; H03K 17/6871

(57) ABSTRACT

A fuse circuit assembly has a first supply path and a second supply path. The first supply path includes a first supply-connection node, a first load-connection node for connecting a safety-relevant load, a first fuse node, a first electrical fuse and a second electrical fuse. The first electrical fuse is arranged between the first supply-connection node and the first fuse node. The second electrical fuse is arranged between the first fuse node and the first load-connection node. The second supply path includes a second supply-connection node, a second load-connection node for connecting the safety-relevant load, and a third electrical fuse which is arranged in a third connection between the second supply-connection node and the second load-connection node. The first fuse node is connected to the second supply-connection node via a fourth electrical fuse.

### CROSS-REFERENCE TO RELATED APPLICATIONS

This application claims the benefit of PCT Application PCT/EP2023/059712, filed Apr. 13, 2023, which claims priority to German Application 10 2022 204 201.8, filed Apr. 29, 2022. The disclosures of the above applications are incorporated herein by reference.

### TECHNICAL FIELD

The disclosure relates to a fuse circuit assembly for an energy system and to an energy system which has the fuse circuit assembly. The disclosure furthermore relates to a vehicle that includes the energy system.

### BACKGROUND

Autonomous driving systems belong to the safety-relevant functions of the vehicle and have to meet special safety requirements. Taking into account the functional safety according to ISO 26262, such functions can be classified with an availability according to classification ASIL C or D. For this purpose, classification is carried out taking into account the severity of the fault as well as the risk to the user or to the environment, the probability of occurrence, i.e. interaction of malfunction and operating state, and the controllability of the fault. This is referred to as the ASIL classification, wherein a distinction is made between four ASIL (Automotive Safety Integrity Level) levels A to D, with ASIL D being the highest safety level.

From the point of view of ISO 26262, three types of faults must be taken into account: Random hardware faults such as a short circuit or data corruption caused by radiation, as well as systematic hardware faults and systematic software faults, that is to say faults in the implementations. With regard to random hardware faults, it must be demonstrated that the probability of safety-relevant faults is sufficiently low. In the case of autonomous driving systems, which have to be designed as fail-operational systems, the focus is therefore no longer only on the avoidance or detection of false behavior but also explicitly on the avoidance of the non-availability of the functions.

In vehicles with electrically supported or purely electrically implemented safety-relevant functions, such as, for example, the steering system or brake, there are therefore high requirements for the availability of the power supply.

FIG. 1 shows a simplified block diagram of an on-board power supply system 1 with redundant power supply. In addition to simple loads 2, e.g. an air conditioning system, the on-board power supply system 1 also supplies power to a plurality of safety-relevant loads 3, e.g. an electric brake, which require a power supply, for example, in compliance with ASIL D or ASIL C. The on-board power supply system 1 has a DC/DC converter 4 and a battery 5 which are connected via a supply line. A circuit breaker 7 between the two sources 4, 5 is used to ensure that there is no reaction in the case of a defective DC/DC converter, or its supply line. The supply line has connection points for connecting the safety-relevant loads 3 and the simple loads 2. The safety-relevant loads 3 and the simple loads 2 are each connected to one of the connection points via a fuse 6, for example a meltable fuse. The ASIL requirements for the fuses 6 are very high in order that, for example, short circuits in the individual load branches only have a very low probability of affecting the power supply to the safety-relevant loads 3. This means that since the power supply to the safety-relevant loads 3 has to meet ASIL-D requirements or ASIL-C requirements, the fuses 6 also have to meet at least ASIL-C requirements in the circuit structure shown in FIG. 1. This can be achieved in each case, for example, by using two series-connected fuses which meet ASIL-B requirements.

### SUMMARY

The disclosure provides a cost-effective fuse circuit assembly that contributes to a high availability of electrically supported or purely electrically implemented safety-relevant functions, in particular in a vehicle.

According to a first aspect of the disclosure, a fuse circuit assembly has a first supply path and a second supply path. The first supply path includes a first supply-connection node which is designed for connection to a first electrical energy source. The first electrical energy source is designed, for example, to provide a predefined DC voltage as a supply voltage for one or more loads or consumers.

Moreover, the first supply path has a first load-connection node for connecting a safety-relevant load. The safety-related load has, for example, an ASIL-C requirement or ASIL-D requirement for a power supply to the safety-relevant load.

The first supply path has a first fuse node and a first electrical fuse, where the first electrical fuse is arranged in a first connection between the first supply-connection node and the first fuse node. This advantageously allows complete line protection to the first electrical energy source.

Furthermore, the first supply path has a second electrical fuse which is arranged in a second connection between the first fuse node and the first load-connection node.

The second supply path includes a second supply-connection node which is designed for connection to a second electrical energy source. The second electrical energy source has, for example, a battery, for example a 12-volt battery.

In addition, the second supply path has a second load-connection node for connecting the safety-relevant load. The second load-connection node is connected to the second supply-connection node via a third electrical fuse. The first fuse node of the first supply path is connected to the second supply-connection node of the second supply path via a fourth electrical connection in which a fourth electrical fuse is arranged.

Implementations of the disclosure may include one or more of the following optional features. In some implementations, the electrical fuses can in each case also be referred to as circuit breakers.

The fuse circuit assembly thus allows a redundant energy supply to the safety-relevant load. The first electrical fuse ensures that there is no reaction in the case of a defective first energy source or its supply line, which leads to a significant increase in the availability of the power supply to the safety-relevant load.

The line protection to the first energy source is complete in this case since a current that is to be measured and that is required for the safe operation of the first electrical fuse can be detected undistorted and is not distorted, for example, by the second electrical fuse which directly protects the load branch.

In one advantageous configuration according to the first aspect, the second supply path has a plurality of third load-connection nodes each for connecting a simple load. In this case, the third load-connection nodes are each connected to the second supply-connection node via a fifth electrical fuse. The simple loads are not safety-relevant or have lower safety requirements than the safety-relevant load. The simple loads are, for example, loads which only have to meet Quality Managed requirements (i.e. are not safety-relevant) or ASIL-A requirements or ASIL-B requirements.

The second electrical fuse and third electrical fuse as well as the fifth electrical fuses allow faults in the load branches to be able to be isolated without any reaction to the redundant power supply. The energy system can thus advantageously be used to operate safety-relevant and simple loads without the electrical fuses in the load branches having to meet very high ASIL requirements. In the event of a fault, it is possible to isolate the power supply to the safety-relevant load from the second energy source and the other loads and to provide the power supply to the safety-relevant load using the first energy source. This thus reduces the requirement for all loads (except for the safety-relevant load itself) with regard to safe shutdown or disconnection from the energy system and so not every load needs to be protected with redundant electrical fuses. For example, a requirement for the second electrical fuse, the third electrical fuse and the fifth electrical fuses can be reduced to an ASIL-B requirement.

In a further advantageous configuration according to the first aspect, the first supply path has at least one further second electrical fuse, at least one further third electrical fuse, at least one further first load-connection node and at least one further second load-connection node for connecting at least one further safety-relevant load. In this case, the at least one further first load-connection node is connected to the first fuse node via the at least one further second electrical fuse, and the at least one further second load-connection node is connected to the second supply-connection node via the at least one further third electrical fuse. Advantageously, a plurality of safety-relevant loads can thus be operated by the energy system at the same time. During fault-free operation, the safety-relevant loads are each connected to the first energy source and the second energy source.

In a further advantageous configuration according to the first aspect, at least some of the electrical fuses each have a controllable semiconductor switch for disconnecting the associated connection. Such electronic fuses (also known as e-fuses) have a significantly shorter reaction time compared to meltable fuses. Another advantage is that they can be reused after fault correction and do not need to be replaced.

In a further advantageous configuration according to the first aspect, the respective semiconductor switch has at least one metal-oxide-semiconductor field-effect transistor, MOSFET. This allows cost-effective provision of the semiconductor switches, in particular in applications in which high currents need to be protected.

In a further advantageous configuration according to the first aspect, the first electrical fuse comprises a first MOSFET and the fourth electrical fuse comprises a second MOSFET. Furthermore, a drain connection of the first MOSFET is connected to a drain connection of the second MOSFET, and a source connection of the first MOSFET is connected to the first supply-connection node, and a source connection of the second

MOSFET is connected to the second supply-connection node. A bidirectional current flow can thus be protected. The drain-drain configuration has the advantage that the MOSFETs can be driven independently of each other and thus a higher reliability can be achieved.

In a further advantageous configuration according to the first aspect, the first electrical fuse is designed to detect a signal which is representative of a current flowing between the first supply-connection node and the first fuse node and to control a switch state of the first electrical fuse on the basis of the detected signal. This has the advantage that the current that is to be measured for the safe operation of the first electrical fuse can be detected very precisely.

Alternatively or in addition, the fourth electrical fuse can be designed to detect a signal which is representative of a current flowing between the first fuse node and the second supply-connection node and to control a switch state of the fourth electrical fuse on the basis of the detected signal.

In a further advantageous configuration according to the first aspect, the fuse circuit assembly has a second fuse node and a sixth electrical fuse in the second supply path. In this case, the sixth electrical fuse is arranged in a fifth connection between the second supply-connection node and the second fuse node. The first fuse node of the first supply path is connected to the second fuse node via the fourth electrical fuse and connected to the second supply-connection node via the fourth electrical fuse and the sixth electrical fuse.

Advantageously, this allows the second energy source and its supply line to be separated from the first supply path in the event of a defective second energy source or its supply line. In this case, the loads can be supplied with power from the first energy source. This is particularly advantageous if the supply line to the second energy source is long, e.g. if the second energy source is arranged outside a housing of the fuse circuit assembly.

In a further advantageous configuration, the first electrical fuse and/or the second electrical fuse and/or the third electrical fuse and/or the fourth electrical fuse and/or the fifth electrical fuse and/or the sixth electrical fuse each have a third MOSFET and a fourth MOSFET which are arranged in a back-to-back configuration, wherein a source connection of the third MOSFET is connected to a source connection of the fourth MOSFET, and a gate of the third MOSFET and a gate of the fourth MOSFET are driven by one and the same gate driver. The third and fourth MOSFET are thus arranged antiserially. Such an arrangement reduces the reactions in the case of defective loads or energy sources.

According to a second aspect, an energy system has a fuse circuit assembly according to the first aspect as well as a first energy source which is connected to the first supply-connection node, and a second energy source which is connected to the second supply-connection node. Advantageous configurations of the first aspect also apply in this case to the second aspect.

In one advantageous configuration according to the second aspect, the energy system has a first diode which is arranged in a connection between the first load-connection node and a supply connection of the safety-relevant load. The safety-relevant load has a second reference potential connection which is connected to ground. The cathode of the first diode is connected to the supply connection of the safety-relevant load. The energy system further has a second diode which is arranged in a further connection between the second load-connection node and the supply connection of the safety-relevant load, wherein the cathode of the second diode is connected to the supply connection of the safety-relevant load, and the first diode and the second diode are arranged antiserially. The diodes can be in the form of diodes in the conventional sense (with two connections) or the first diode and/or second diode can be formed by actively switchable transistors, e.g. MOSFETs, in order to reduce power losses.

According to a third aspect, a vehicle has an energy system according to the second aspect. Advantageous configurations of the first and second aspects also apply to the third aspect.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows an on-board power supply system according to the prior art.

FIG. 2 shows an exemplary equivalent circuit diagram of a first fuse circuit assembly for an energy system.

FIG. 3 shows an exemplary equivalent circuit diagram of a second fuse circuit assembly.

FIG. 4 shows an exemplary equivalent circuit diagram of a third fuse circuit assembly.

FIG. 5 shows an exemplary equivalent circuit diagram of the energy system.

FIG. 6 shows an exemplary equivalent circuit diagram of a fourth fuse circuit assembly.

Like reference symbols in the various drawings indicate like elements.

### DETAILED DESCRIPTION

It is understood that if an element is referred to as being “connected” or “coupled” to another element, the element may be connected or coupled to the other element directly or intermediate elements may be present. In contrast, if an element is referred to as being “directly connected” or “directly coupled” to another element, no intermediate elements are present.

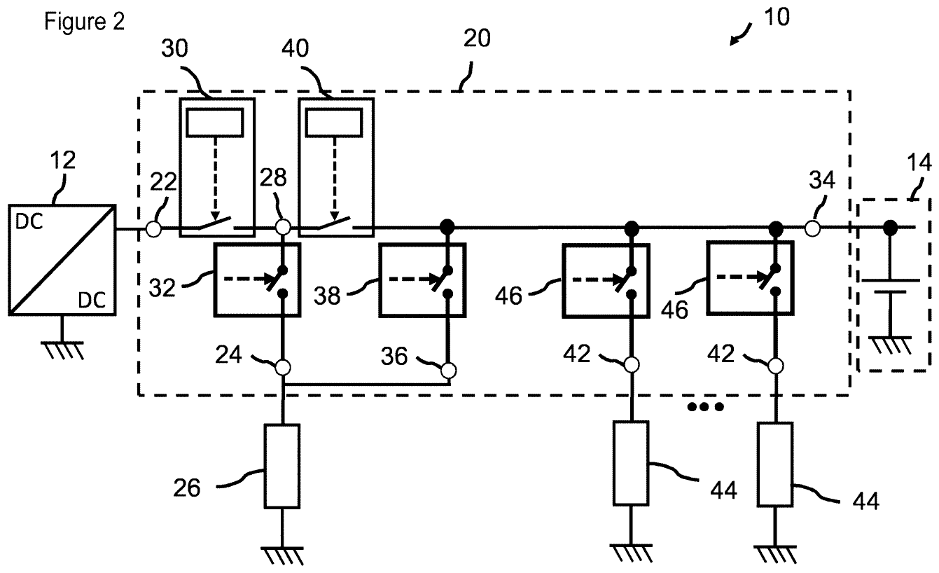

FIG. 2 shows an exemplary equivalent circuit diagram of a fuse circuit assembly for an energy system.

The energy system 10 has, for example, a first energy source 12 and a second energy source 14. The first energy source 12 and the second energy source 14 are designed, for example, to provide a DC voltage, such as an equal DC voltage.

The first energy source 12 comprises, for example, a DC/DC converter. The DC/DC converter provides, for example, a 12-volt voltage at its output.

The second energy source 14 includes, for example, a battery. The battery likewise provides, for example, a 12-volt voltage.

Alternatively, the first energy source 12 may have a battery and the second energy source 14 may have a DC/DC converter.

The energy system 10 is arranged, for example, in a vehicle. The energy system 10 can also be referred to as an on-board power supply system.

The fuse circuit assembly 20 has a first supply path having a first supply-connection node 22 and a second supply path having a second supply-connection node 34. The fuse circuit assembly 20 is connected to the first energy source 12 via the first supply-connection node 22 and to the second energy source 14 via the second supply-connection node 34.

The first supply path has a first load-connection node 24 and a first fuse node 28. A safety-relevant load 26 is connected to the first load-connection node 24. The first fuse node 28 is connected to the first supply-connection node 22 via a first electrical fuse 30.

A safety-relevant load with a high availability requirement is, for example, an electric steering system which is assigned a requirement according to ASIL C or ASIL D for a reliable power supply. This means that it is important that this load is supplied with stable electrical power under virtually all circumstances.

The second supply path has a second load-connection node 36 which is likewise connected to the safety-relevant load 26. The first load-connection node 24 and the second load-connection node 36 are connected in an electrically conductive manner. Alternatively, the first load-connection node 24 may be the same as the second load-connection node 36. The second load-connection node 36 is connected to the second supply-connection node 36 via a third electrical fuse 38.

The first fuse node 28 of the first supply path is connected to the second supply-connection node 34 of the second supply path via a fourth electrical fuse 40.

In some examples, the second supply path has a plurality of third load-connection nodes 42 to each of which a simple load 44 is connected. The third load-connection nodes 42 are each connected to the second supply-connection node 34 via a fifth electrical fuse 46. The simple loads 44 are not safety-relevant or have lower safety requirements than the safety-relevant loads 26.

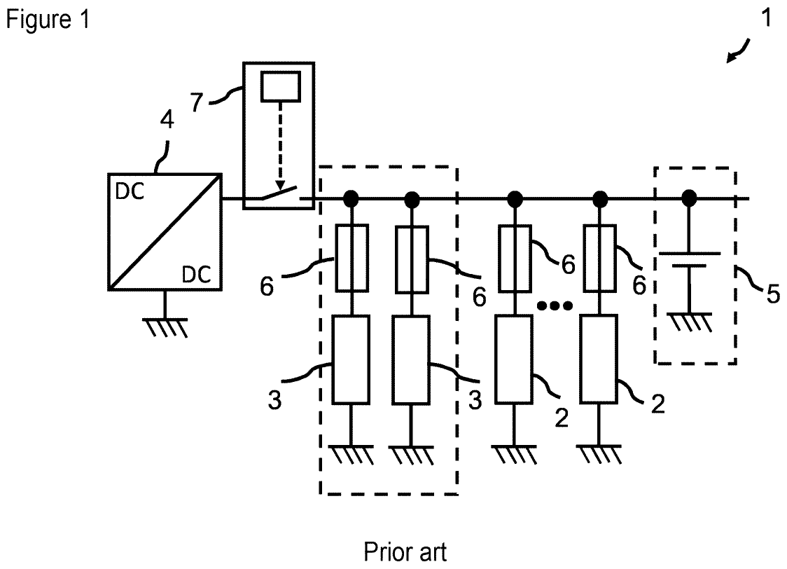

In the prior art (see FIG. 1), the ASIL-C or ASIL-D requirement for the availability of the power supply to the safety-relevant loads 3 is changed to the criterion of safe shutdown. This means that all loads 2, 3 or consumers must be able to be disconnected from the energy system via a circuit breaker or a fuse which meets ASIL-C or ASIL-D requirements. If a load cannot be safely switched off with the same probability (completely without any reaction), the safe power supply in accordance with ASIL C or ASIL D for the steering system cannot be guaranteed due to the electrical coupling.

In order to reduce the requirements for the fuses or circuit breakers with regard to safe shutdown, according to the disclosure the circuit breaker shown in the prior art, which is arranged in the connection connecting the two energy sources, is “disconnected” and used as a redundant shutdown option. This means that the safety-relevant load (e.g. steering system) is branched or connected once before (coming from the side of the second energy source) the circuit breaker and once in the circuit breaker. This ensures a redundant electrical power supply. In the event of a fault, it is furthermore possible to isolate the electrical power supply to the safety-relevant load from the second energy source and the other loads and to provide the power supply to the safety-relevant load using the first energy source. This thus reduces the requirement for all loads (except for the safety-relevant load itself) with regard to safe shutdown or disconnection from the energy system and so not every load needs to be protected with redundant electrical fuses. For example, a requirement for the second electrical fuse, the third electrical fuse and the fifth electrical fuse can, for example, be reduced to an ASIL-B requirement.

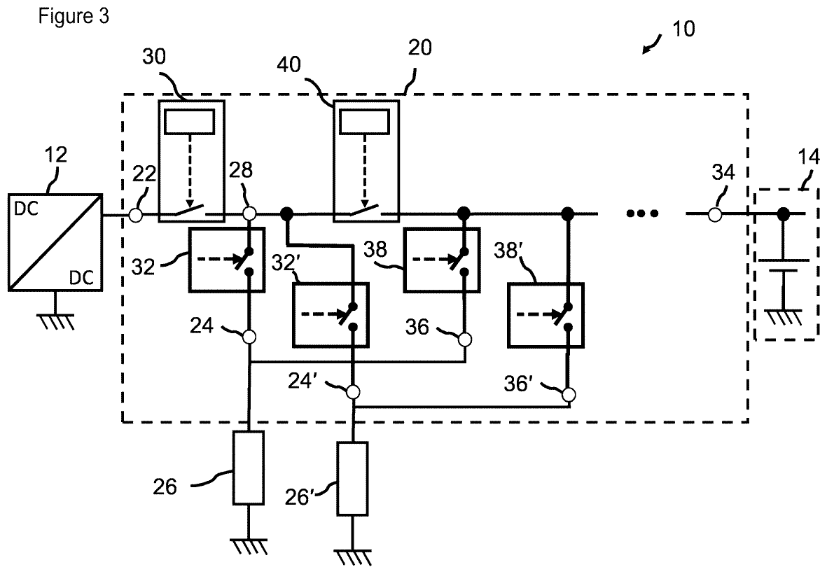

FIG. 3 shows an exemplary equivalent circuit diagram of a large fuse circuit assembly for an energy system in which a plurality of safety-relevant loads are connected to the redundantly designed energy system.

In contrast to the example shown in FIG. 2, the first supply path has at least one further second electrical fuse 32′, at least one further third electrical fuse 38′, at least one further first load-connection node 24′ and at least one further second load-connection node 36′ for connecting at least one further safety-relevant load 26′.

The at least one further first load-connection node 24′ is connected to the first fuse node 28 via the at least one further second electrical fuse 32′, and the at least one further second load-connection node 36′ is connected to the second supply-connection node 34 via the at least one further third electrical fuse 38′.

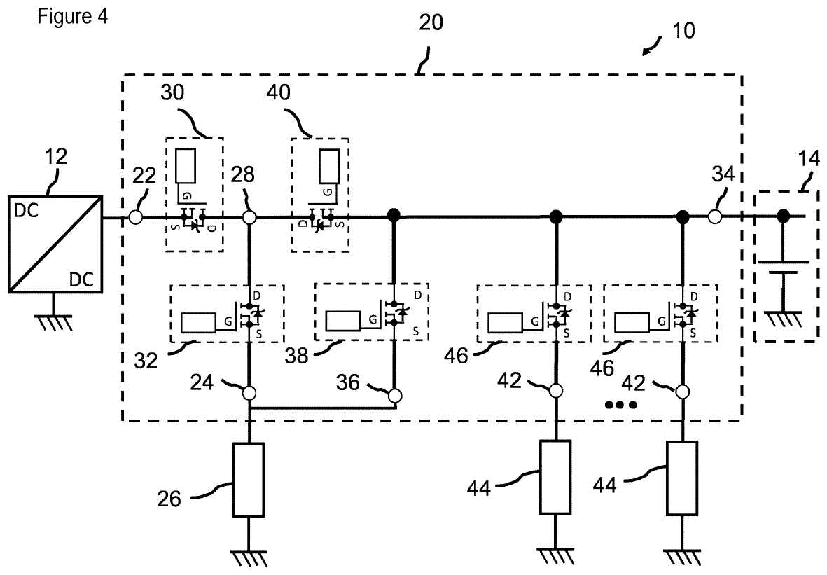

FIG. 4 shows an exemplary equivalent circuit diagram of a further fuse circuit assembly 20 for an energy system 10.

The first electrical fuse 30 and/or the second electrical fuse 32 and/or the third electrical fuse 38 and/or the fourth electrical fuse 40 and/or the fifth electrical fuses 46 each have, for example, a controllable semiconductor switch for disconnecting the associated connections.

The semiconductor switches each have, for example, at least one metal-oxide-semiconductor field-effect transistor, MOSFET. The MOSFETs are, for example, in the form of n-channel MOSFETs.

In some examples, the first electrical fuse 30 has a first MOSFET and the fourth electrical fuse 40 has a second MOSFET, and a drain connection of the first MOSFET is connected to a drain connection of the second MOSFET. Furthermore, a source connection of the first MOSFET is connected to the first supply-connection node 22 and a source connection of the second MOSFET is connected to the second supply-connection node 34.

The semiconductor switches of the first to fifth electrical fuse may have the same or a different design.

For example, one or more of the semiconductor switches may have a parallel connection of a plurality of MOSFETs.

Optionally, the first electrical fuse 30 and/or the second electrical fuse 32 and/or the third electrical fuse 38 and/or the fourth electrical fuse 40 and/or the fifth electrical fuses 50 each have a third MOSFET and a fourth MOSFET which are arranged in a back-to-back configuration, where a source connection of the third MOSFET is connected to a source connection of the fourth MOSFET, and a gate of the third MOSFET and a gate of the fourth MOSFET are driven by one and the same gate driver. For the first electrical fuse 30, the first MOSFET and the third MOSFET may be identical, and for the fourth electrical fuse 40, the second MOSFET and the fourth MOSFET may be identical.

Alternatively, it is possible for the first fuse 30 not to be embodied in a source-source configuration but in a drain-drain configuration. This requires more complex control of the MOSFETs but allows overvoltages to be better absorbed.

Alternatively or in addition, one or more of the semiconductor switches or of the first to fifth electrical fuses 30, 32, 38, 40, 46 may have a plurality of parallel switching paths in each of which two MOSFETs are arranged in a back-to-back configuration.

Alternatively or in addition, it is possible for one or more of the first to fifth electrical fuses 30, 32, 38, 40, 46 to have a multi-level design, that is to say to have a series connection of at least two semiconductor switches.

In some examples, the first electrical fuse 30 is designed to detect a signal which is representative of a current flowing between the first supply-connection node 22 and the first fuse node 28 and to control a switch state of the first electrical fuse 30 on the basis of the detected signal. Alternatively or in addition, the other electrical fuses are also designed to

detect a signal which is representative of a current flowing through the connection which they respectively protect, and to control their switch state on the basis of the detected signal.

At least some of the first to fifth electrical fuses 30, 32, 38, 40, 46 have, for example, a shunt resistor (not shown in the figures) which is arranged in series with the semiconductor switch of the respective electrical fuse. Alternatively, use may in each case also be made of a sense-current transistor in which, for example, a fraction (e.g. 1/20000) of the load current is used to measure the current strength.

Furthermore, the respective electrical fuses 30, 32, 38, 40, 46 have, for example, an evaluation unit (not shown in the figures) which is designed to detect a voltage which is dropped across the shunt resistor and, for example, to compare the voltage with a predefined threshold value and, if the detected voltage exceeds the predefined threshold value, to actuate the semiconductor switch so that it transitions to an open state.

In some implementations, at least some of the first to fifth electrical fuses 30, 32, 38, 40, 46 each have a control connection (not shown in the figures) so that the electrical fuses 30, 32, 38, 40, 46, after correction of a fault which tripped the respective electrical fuse 30, 32, 38, 40, 46, can be returned to a closed state for normal operation.

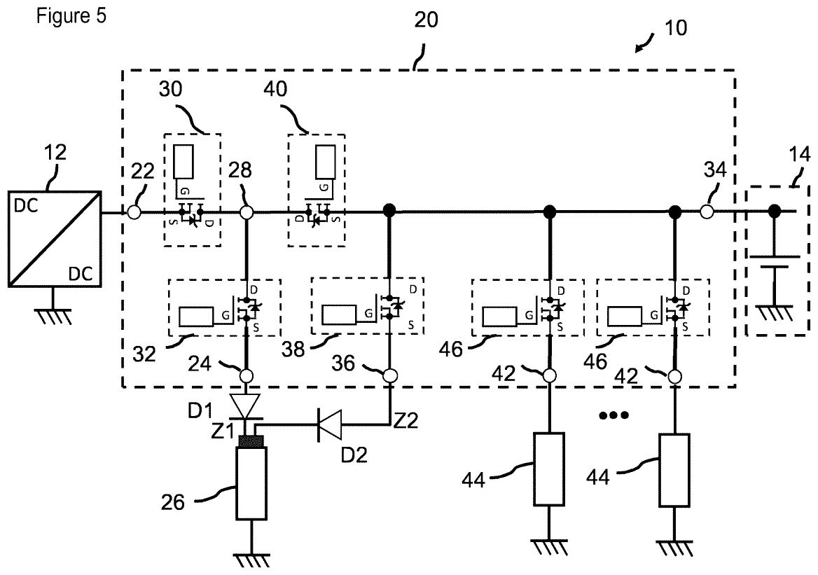

In FIG. 5, an exemplary equivalent circuit diagram of a further example of the energy system 10 is shown. In contrast to the examples shown in FIGS. 2 to 4 and 6, the safety-relevant load 26 is supplied with power, for example, via two supply lines Z1, Z2. A diode D1, D2 is arranged in each supply line Z1, Z2, the cathode of each diode being connected to the supply connection of the safety-relevant load 26. The diodes D1, D2 are thus arranged antiserially. The first diode DI and second diode D2 may be arranged inside a housing of the fuse circuit assembly 20 or outside the housing of the fuse circuit assembly 20.

The use of the first diode DI and second diode D2 is advantageous if the second and third electrical fuses 32, 38 each have no equivalent diode blocking function, for example because only a simple switching transistor is used in each case. The use of the diodes D1, D2 is advantageous if the load current of the safety-relevant load 26 is small (e.g. less than 20 amperes) since simple diodes can be used in this case. For loads with higher load currents, the use of a (controllable) semiconductor switch with two antiserially arranged transistors, such as MOSFETs, is advantageous.

Otherwise, the fuse circuit assembly 20 shown in FIG. 5 may be designed analogously to the fuse circuit assembly 20 shown in FIG. 4.

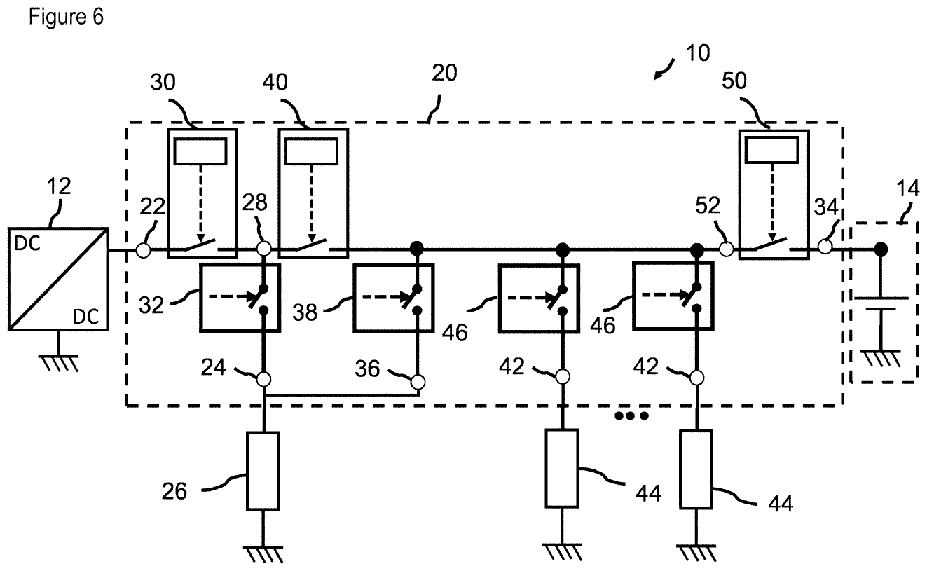

In FIG. 6, an exemplary equivalent circuit diagram of a fifth example of the fuse circuit assembly 20 is shown. FIG. 6 shows a variant in which the fuse circuit assembly 20 has a second fuse node 52 and a sixth electrical fuse 50 in the second supply path. The sixth electrical fuse 50 is arranged between the second supply-connection node 34 and the second fuse node 52. The first fuse node 28 of the first supply path is connected to the second fuse node 52 via the fourth electrical fuse 40. Otherwise, the fuse circuit assembly 20 may be designed analogously to the fuse circuit assemblies shown in FIGS. 2 to 5.

The sixth electrical fuse 50 may be designed analogously to one of the first to fifth electrical fuses 30, 32, 38, 40, 46.

A number of implementations have been described. Nevertheless, it will be understood that various modifications may be made without departing from the spirit and scope of the disclosure. Accordingly, other implementations are within the scope of the following claims.

### LIST OF REFERENCE SIGNS

1 on-board power supply system
2 simple load
3 safety-related load
4 DC/DC converter
5 battery
6 fuse
7 circuit breaker
10 energy system
12 first energy source
14 second energy source
20 fuse circuit assembly
22 first supply-connection node
24 first load-connection node
24′ further first load-connection node
26 safety-related load
26′ further safety-related load
28 first fuse node
30 first electrical fuse
32 second electrical fuse
32′ further second electrical fuse
34 second supply-connection node
36 second load-connection node
36′ further second load-connection node
38 third electrical fuse
38′ further third electrical fuse
40 fourth electrical fuse
42 third load-connection node
44 simple load
46 fifth electrical fuse
50 sixth electrical fuse
52 second fuse node
D1, D2 diode
Z1, Z2 supply line

What is claimed is:

1. A fuse circuit assembly for an energy system comprising:
a first supply path including:
a first supply-connection node designed to connect the first supply path to a first energy source,
a first load-connection node for connecting a safety-relevant load,
a first fuse node and a first electrical fuse, the first electrical fuse arranged in a first connection between the first supply-connection node and the first fuse node, and
a second electrical fuse arranged in a second connection between the first fuse node and the first load-connection node; and
a second supply path including:
a second supply-connection node designed to connect the second supply path to a second energy source,
a second load-connection node for connecting the safety-relevant load,
a third electrical fuse which is arranged in a third connection between the second supply-connection node and the second load-connection node,
wherein the first fuse node of the first supply path is connected to the second supply-connection node of the second supply path via a fourth electrical connection in which a fourth electrical fuse is arranged.

2. The fuse circuit assembly of claim 1, wherein the second supply path includes a plurality of third load-connection nodes each for connecting a simple load, the third load-connection nodes are each connected to the second supply-connection node via a fifth electrical fuse and the simple loads are not safety-relevant or have lower safety requirements than the safety-relevant load.

3. The fuse circuit assembly of claim 1, wherein the first supply path includes:
at least one further second electrical fuse;
at least one further third electrical fuse;
at least one further first load-connection node; and
at least one further second load-connection node for connecting at least one further safety-relevant load,
wherein the at least one further first load-connection node is connected to the first fuse node via the at least one further second electrical fuse, and the at least one further second load-connection node is connected to the second supply-connection node via the at least one further third electrical fuse.

4. The fuse circuit assembly of claim 1, wherein at least some of the electrical fuses each have a controllable semiconductor switch for disconnecting the associated connection.

5. The fuse circuit assembly of claim 4, wherein the respective semiconductor switch has at least one metal-oxide-semiconductor field-effect transistor, MOSFET.

6. The fuse circuit assembly of claim 1, wherein the first electrical fuse has a first MOSFET and the fourth electrical fuse has a second MOSFET, and a drain connection of the first MOSFET is connected to a drain connection of the second MOSFET, and a source connection of the first MOSFET is connected to the first supply-connection node, and a source connection of the second MOSFET is connected to the second supply connection.

7. The fuse circuit assembly of claim 1, wherein:
the first electrical fuse is designed to detect a signal which is representative of a current flowing between the first supply-connection node and the fuse node and to control a switch state of the first electrical fuse based on the detected signal, and/or
the fourth electrical fuse is designed to detect a signal which is representative of a current flowing between the first fuse node and the second supply-connection node and to control a switch state of the fourth electrical fuse based on the detected signal.

8. The fuse circuit assembly of claim 1, wherein the fuse circuit assembly includes a second fuse node and a sixth electrical fuse in the second supply path, the sixth electrical fuse is arranged in a fifth connection between the second supply-connection node and the second fuse node and the first fuse node of the first supply path is connected to the second fuse node via the fourth electrical fuse.

9. The fuse circuit assembly of claim 1, wherein one or more or all of the electrical fuses each have a third MOSFET and a fourth MOSFET which are arranged in a back-to-back configuration, wherein a source connection of the third MOSFET is connected to a source connection of the fourth MOSFET, and a gate of the third MOSFET and a gate of the fourth MOSFET are driven by one and the same gate driver.

10. An energy system comprising a fuse circuit assembly of claim 1, and the first energy source which is connected to the first supply-connection node, and the second energy source which is connected to the second supply-connection node.

11. The energy system of claim 9, wherein the energy system comprises:
a first diode arranged in a connection between the first load-connection node and a supply connection of the safety-relevant load, a cathode of the first diode connected to the supply connection of the safety-relevant load, and
a second diode arranged in a further connection between the second load-connection node and the supply connection of the safety-relevant load, wherein a cathode of the second diode is connected to the supply connection of the safety-relevant load, and the first diode and the second diode are arranged antiserially.
